(19) United States
(12) Patent Application Publication
(10) Pub. No.: US 2026/0136847 A1
(43) Pub. Date: May 14, 2026

(54) METHOD FOR MANUFACTURING SEMICONDUCTOR DEVICE

(71) Applicant: HAMAMATSU PHOTONICS K.K., Hamamatsu-shi (JP)

(72) Inventors: Takashi SENGA, Shizuoka (JP); Ryuji OKUMURA, Shizuoka (JP)

(73) Assignee: HAMAMATSU PHOTONICS K.K., Hamamatsu-shi (JP)

(21) Appl. No.: 19/380,346

(22) Filed: Nov. 5, 2025

(30) Foreign Application Priority Data
Nov. 8, 2024 (JP) 2024-195910

(51) Int. Cl. H01L 21/02

(52) U.S. Cl. CPC H10P 14/3602; H10P 14/2909; H10P 14/3418

(57) ABSTRACT

A method for manufacturing a semiconductor device comprising a first semiconductor made of InP or InGaAsP and a second semiconductor provided on the first semiconductor, the method comprising: performing thermal cleaning on a surface of the first semiconductor in a growth furnace in an atmosphere containing arsine; and growing the second semiconductor on the surface of the first semiconductor in the growth furnace. A set temperature of the growth furnace during the thermal cleaning is lower than a set temperature of the growth furnace during the growing of the second semiconductor.

### CROSS-REFERENCE TO RELATED APPLICATION

This application claims priority to Japanese Patent Application No. 2024-195910, filed on Nov. 8, 2024, the entire contents of which are incorporated herein by reference.

### TECHNICAL FIELD

The present disclosure relates to a method for manufacturing a semiconductor device.

### BACKGROUND

Japanese Unexamined Patent Application Publication No. H1-197398 discloses a vapor-phase growth method for performing crystal growth on an InP substrate. In this method, before starting the crystal growth, the InP substrate is heated to 700° C. or higher while supplying phosphine (PH₃) gas at a flow rate of 5×10⁻³ mol/min or more. Japanese Unexamined Patent Application Publication No. 2000-124138 discloses a surface treatment method and a semiconductor device. Japanese Unexamined Patent Application Publication No. H11-204877 discloses a semiconductor laser and a method for manufacturing the same.

### SUMMARY

Generally, in a semiconductor device such as a high electron mobility transistor (HEMT) comprising a GaAs-based semiconductor, an undoped epitaxial layer is grown on a substrate. At that time, if silicon (Si) impurities are present at an interface between the epitaxial layer and the substrate, the epitaxial layer becomes conductive, and electrical characteristics of the semiconductor device deteriorate due to current leakage or the like. In order to improve such problems, various studies have been conducted on semiconductor devices comprising GaAs-based semiconductors.

On the other hand, when another semiconductor layer is grown on a substrate or a semiconductor layer comprising InP or InGaAsP, unintentional incorporation of Si atoms occurs at an interface between the substrate or the semiconductor layer and the other semiconductor layer. For example, when manufacturing a photodiode comprising an InP-based semiconductor, problems such as an unintentional increase in device capacitance occur due to the incorporation of Si atoms. Therefore, it is desirable to reduce or remove Si atoms at the interface between the substrate or the semiconductor layer and the other semiconductor layer. Generally, when growing a semiconductor on an InP substrate, in order to remove a native oxide film on the InP substrate, thermal treatment is performed in an atmosphere of a group V source gas of the substrate material, that is, phosphine (PH₃). However, it is difficult to remove Si atoms by thermal treatment in a PH₃ atmosphere.

An object of the present disclosure is to provide a method for manufacturing a semiconductor device that can reduce or remove Si atoms at an interface between a substrate or a semiconductor layer comprising InP or InGaAsP and another semiconductor layer grown thereon.

A method for manufacturing a semiconductor device according to one aspect of the present disclosure is a method for manufacturing a semiconductor device comprising a first semiconductor made of InP or InGaAsP and a second semiconductor provided on the first semiconductor. The method comprises a first step and a second step. In the first step, thermal cleaning is performed on a surface of the first semiconductor in a growth furnace in an atmosphere containing arsine. In the second step, the second semiconductor is grown on the surface of the first semiconductor in the growth furnace. A set temperature of the growth furnace during the thermal cleaning is set lower than a set temperature of the growth furnace during the growing the second semiconductor.

According to the present disclosure, it is possible to provide a method for manufacturing a semiconductor device that can reduce or remove Si atoms at an interface between a substrate or a semiconductor layer comprising InP or InGaAsP and another semiconductor layer grown thereon.

The present invention will be more fully understood from the detailed description given herein below and the accompanying drawings, which are given by way of illustration only and are not to be considered as limiting the present invention.

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will be apparent to those skilled in the art from this detailed description.

### BRIEF DESCRIPTION OF THE DRAWINGS

FIG. 1 is a side view showing a part of a configuration of a semiconductor device manufactured by a manufacturing method according to an embodiment.

FIGS. 2A and 2B are diagrams showing a manufacturing method according to an embodiment.

FIG. 3 is a diagram showing a temporal change in a set temperature in a growth furnace.

FIG. 4 is a diagram showing a temporal change in a set temperature in a growth furnace in a comparative example.

FIG. 5 is a graph showing a profile of Si concentration in a thickness direction for four samples prepared in a comparative example.

FIG. 6 shows a micrograph of a surface of an InP substrate after thermal cleaning.

FIG. 7 is a diagram showing a temporal change in a set temperature in a growth furnace in a comparative example.

FIGS. 8A and 8B are micrographs of a surface of an InP substrate.

FIGS. 9A and 9B are micrographs of a surface of an InP substrate.

FIGS. 10A and 10B are micrographs of a surface of an InP substrate.

FIGS. 11A and 11B are micrographs of a surface of an InP substrate after thermal cleaning in a reference example.

FIGS. 12A and 12B are micrographs of a surface of an InP substrate after thermal cleaning in a reference example.

FIG. 13A is an enlarged view of unintended deposits. FIG. 13B is a graph showing a result of analyzing the unintended deposits by energy dispersive X-ray spectroscopy.

FIG. 14 is a graph showing a profile of Si concentration in a thickness direction of samples of three groups prepared in an example.

FIG. 15 shows a micrograph of a surface of an InP substrate after thermal cleaning.

FIG. 16 is a graph showing a profile of Si concentration in a thickness direction of samples of five groups prepared in an example.

FIG. 17 is a chart showing a ratio of a total supply amount of AsH₃ to a volume of a growth furnace and an incorporation amount of Si atoms (Si concentration) for four samples subjected to thermal cleaning.

FIG. 18 is a graph showing a profile of Si concentration in a thickness direction of samples of five groups prepared in an example.

FIG. 19 is a graph showing a concentration profile of oxygen (O) atoms in a thickness direction.

FIG. 20 is a graph showing a concentration profile of carbon (C) atoms in a thickness direction.

### DETAILED DESCRIPTION

Specific examples of the present disclosure will be described below with reference to the drawings. The present invention is not limited to these examples, but is indicated by the scope of the claims, and is intended to include all modifications within the meaning and scope equivalent to the scope of the claims. In the following description, the same elements in the description of the drawings are denoted by the same reference numerals, and redundant description will be omitted.

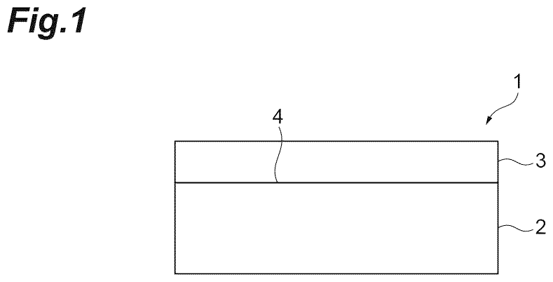

FIG. 1 is a side view showing a part of a configuration of a semiconductor device 1 manufactured by a manufacturing method according to an embodiment of the present disclosure. The semiconductor device 1 is, for example, a photodiode, and in one example, is a waveguide-type photodiode monolithically formed on a waveguide substrate. Alternatively, the semiconductor device 1 may be a transistor such as a HEMT. The semiconductor device 1 comprises at least a first semiconductor 2 and a second semiconductor 3. The semiconductor device 1 may further comprise another semiconductor layer (not shown) on the second semiconductor 3. The first semiconductor 2 is a substrate or a semiconductor layer formed on a substrate. The first semiconductor 2 comprises InP or InGaAsP. The InGaAsP is, for example, (InP)_{1-z}(In_{0.53}Ga_{0.47}As)_{z} (where 0≤z<1) which is lattice-matched to InP. The first semiconductor 2 necessarily contains both indium (In) and phosphorus (P) in its composition. The first semiconductor 2 may or may not contain arsenic (As) in its composition. The second semiconductor 3 is a semiconductor layer epitaxially grown on the first semiconductor 2 and is in contact with the first semiconductor 2. The second semiconductor 3 mainly comprises an InP-based semiconductor that is lattice-matched to the first semiconductor 2. The semiconductor device 1 has an interface 4 between the first semiconductor 2 and the second semiconductor 3.

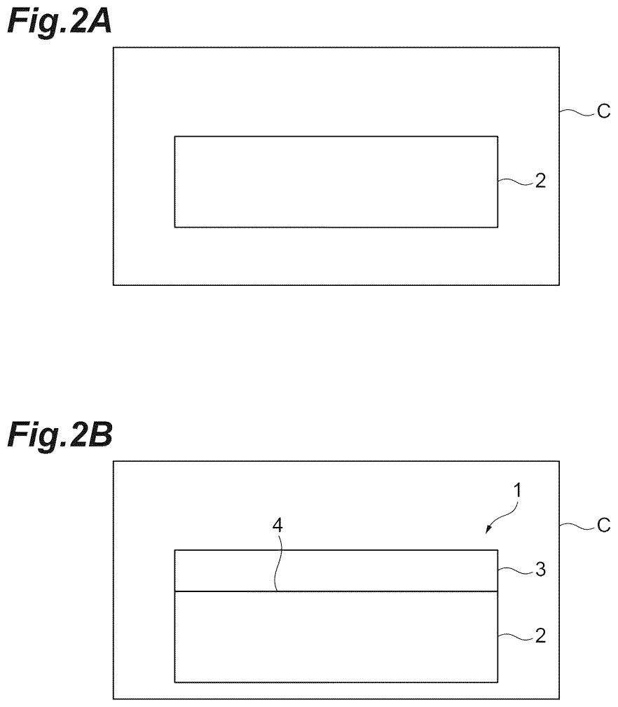

FIGS. 2A and 2B are diagrams showing a manufacturing method according to an embodiment of the present disclosure. The manufacturing method of this embodiment comprises the first step and the second step. In the first step, as shown in FIG. 2A, thermal cleaning is performed on a surface of the first semiconductor 2 in a growth furnace C in an atmosphere containing arsine (AsH₃). Subsequently, in the second step, as shown in FIG. 2B, the second semiconductor 3 is grown on the surface of the first semiconductor 2 in the same growth furnace C.

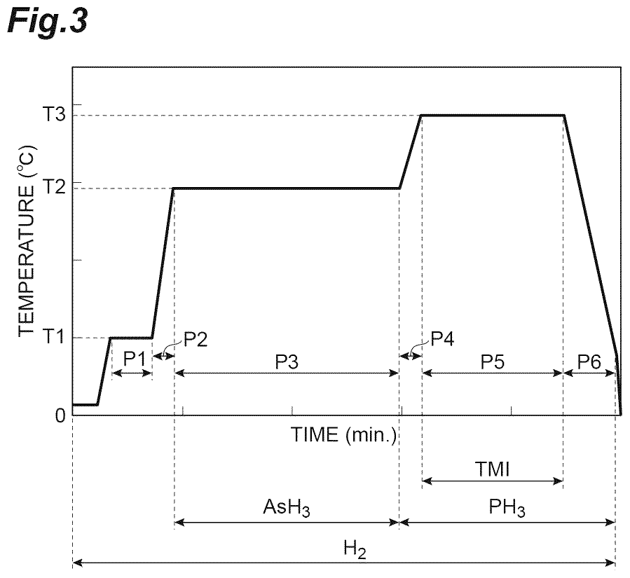

FIG. 3 is a diagram showing a temporal change in a set temperature of the growth furnace C. In FIG. 3, the vertical axis represents temperature (° C.), and the horizontal axis represents time (minutes). FIG. 3 also shows the types of gases supplied at each time.

As shown in FIG. 3, this manufacturing method includes at least six steps P1 to P6. Through steps P1 to P6, a carrier gas (e.g., H2) is supplied into the growth furnace C. In step P1, the first semiconductor 2 is preheated. A set temperature T1 in the growth furnace C in step P1 is, for example, 200° C. In the subsequent step P2, the set temperature of the growth furnace C is raised from the set temperature T1 to a set temperature T2, which is higher than the set temperature T1.

The subsequent step P3 is the first step described above. In step P3, by supplying AsH₃ into the growth furnace C, the inside of the growth furnace C is filled with an atmosphere containing AsH₃. For example, the inside of the growth furnace C is filled with an atmosphere containing only AsH₃ and carrier gas. In other words, the inside of the growth furnace C is filled with an atmosphere that does not contain source gases for III-V semiconductors other than AsH₃. A supply rate of AsH₃ is, for example, 1 slm. 1 slm is equal to 1.67×10⁻⁵ m³/s. Then, by maintaining the set temperature of the growth furnace C at the set temperature T2, thermal cleaning is performed on the surface of the first semiconductor 2. The set temperature T2 is, for example, lower than 650° C., or 595° C. or less. The set temperature T2 is, for example, 540° C. or more. In one example, the set temperature T2 is 585° C. A processing time of the thermal cleaning, that is, the time for which the set temperature of the growth furnace C is maintained at the set temperature T2, is, for example, 30 minutes or more, or 60 minutes or more. In step P3, a total supply amount of AsH₃ is, for example, 50% or more, or 100% or more with respect to a volume of the growth furnace C. The total supply amount of AsH₃ is a product of a supply rate (flow rate) of AsH₃ and time. A root mean square roughness (RMS) of the surface of the first semiconductor 2 after the thermal cleaning is, for example, 0.3 nm or less.

Normally, the temperature of an object placed in the growth furnace C deviates from the set temperature of the growth furnace C. In the growth furnace used by the present inventors, when the set temperature of the growth furnace C was 650° C., 595° C., and 540° C., the temperature of the object placed in the growth furnace C was 534° C., 476° C., and 417° C., respectively. Therefore, a temperature of the first semiconductor 2 during the thermal cleaning is, for example, lower than 534° C., or 476° C. or less. The temperature of the first semiconductor 2 during the thermal cleaning is, for example, 417° C. or more. In one example, the temperature of the first semiconductor 2 during the thermal cleaning is 417° C. or more and 476° C. or less.

The measurement of the temperature of the object placed in the growth furnace C with respect to the set temperature of the growth furnace C was performed by the following method in a hydrogen atmosphere in the growth furnace C. That is, the temperature of a thermocouple was brought to each target temperature, and the process waited until the temperature of the thermocouple stabilized. After confirming that the temperature of the thermocouple had stabilized, the temperature of a substrate placement area during growth in the growth furnace C was measured using a radiation thermometer. At this time, while rotating a susceptor, the temperature was measured at a plurality of locations within the substrate placement area. Thereafter, an average value of the measured temperatures was calculated. This average value is the 534° C., 476° C., and 417° C. described above.

The relationship between the temperature of the object placed in the growth furnace C and the set temperature of the growth furnace C differs depending on the growth furnace used. Therefore, it is advisable to determine the set temperature of the growth furnace C by examining the relationship between the temperature of the object placed in the growth furnace C and the set temperature of the growth furnace C, and applying the above-described temperature range of the first semiconductor 2 to that relationship.

Subsequently, in step P4, the supply of AsH₃ is stopped and the supply of PH₃ is started, thereby changing the atmosphere in the growth furnace C to an atmosphere containing PH₃ in place of AsH₃. For example, the inside of the growth furnace C is filled with an atmosphere containing only PH₃ and carrier gas. Then, the temperature in the growth furnace C is raised from the set temperature T2 to a set temperature T3, which is higher than the set temperature T2. In the thermal cleaning of step P3 described above, it is preferable that a flow rate of the AsH₃ is larger than a flow rate of the PH₃ in step P4.

Step P5 is the second step described above. Subsequently, in step P5, while maintaining the set temperature of the growth furnace C at the set temperature T3, other group V source gases and group III source gases are supplied in addition to PH₃, thereby growing the second semiconductor 3 on the first semiconductor 2. If necessary, other semiconductor layers on the second semiconductor 3 are also grown successively. The other group V source gases and group III source gases are selected according to the composition of the second semiconductor 3. When the second semiconductor 3 comprises InP, the group III source gas is, for example, trimethylindium (TMI). The set temperature T3 is determined depending on the composition of the second semiconductor 3. The set temperature T3 is, for example, 775° C. or more. The time for the thermal cleaning in step P3 described above is set to be longer than a growth time of the second semiconductor 3 in step P5. Finally, in step P6, the supply of PH₃, the other group V source gases, and the group III source gases is stopped, the set temperature of the growth furnace C is lowered, and then the semiconductor device 1 is taken out from the growth furnace C.

The effects obtained by the method for manufacturing the semiconductor device 1 according to this embodiment, as described above, will be described. The present inventors have found that Si atoms present on the surface of a substrate or a semiconductor layer comprising InP or InGaAsP can be removed by performing thermal cleaning in an AsH₃ atmosphere. When performing thermal cleaning on the surface of a semiconductor made of InP or InGaAsP, if the substrate temperature is high, phosphorus atoms are desorbed due to thermal degradation of InP or InGaAsP, and indium atoms precipitate. When thermal cleaning is performed in an AsH₃ atmosphere, arsenic atoms bond to the indium atoms, and unintended deposits are generated on the surface. Therefore, the set temperature T2 in the growth furnace C during the thermal cleaning is set lower than the set temperature T3 of the growth furnace C during the growing the second semiconductor 3. This can prevent thermal degradation of InP or InGaAsP, reduce the desorption of phosphorus atoms, and reduce the generation of unintended deposits. From the above, according to the manufacturing method of this embodiment, it is possible to reduce or remove Si atoms while reducing the generation of unintended deposits at the interface 4 between the substrate or semiconductor layer comprising InP or InGaAsP, i.e., the first semiconductor 2, and another semiconductor layer grown thereon, i.e., the second semiconductor 3. Furthermore, according to the method of this embodiment, a native oxide film on the first semiconductor 2 can also be reduced or removed by the thermal cleaning.

As described above, the temperature of the first semiconductor 2 during the thermal cleaning may be lower than 534° C. In this case, as shown in the examples described later, thermal degradation of InP or InGaAsP can be reliably prevented. Alternatively, the temperature of the first semiconductor 2 during the thermal cleaning may be 476° C. or less. In this case, thermal degradation of InP or InGaAsP can be more reliably prevented.

As described above, the temperature of the first semiconductor 2 during the thermal cleaning may be 417° C. or more. In this case, as shown in the examples described later, Si atoms can be further reduced.

As described above, the temperature of the first semiconductor 2 during the thermal cleaning may be 417° C. or more and 476° C. or less. In this case, it is possible to achieve both further reduction of Si atoms and more reliable prevention of thermal degradation of InP or InGaAsP.

As described above, the processing time of the thermal cleaning may be 30 minutes or more. In this case, as shown in the examples described later, Si atoms can be further reduced. If the processing time is 60 minutes or more, Si atoms can be significantly reduced.

As described above, in the thermal cleaning, the total supply amount of AsH₃ may be 50% or more with respect to the volume of the growth furnace C. In this case, as shown in the examples described later, Si atoms can be further reduced. If the total supply amount of AsH₃ is 100% or more with respect to the volume of the growth furnace C, Si atoms can be significantly reduced.

As described above, the root mean square roughness of the surface of the first semiconductor 2 after the thermal cleaning may be 0.3 nm or less. According to the manufacturing method of this embodiment, it is thus possible to obtain the semiconductor device 1 with less damage to the surface of the first semiconductor 2.

As described above, the time for the thermal cleaning may be longer than the growth time of the second semiconductor 3. In this case, since the time for the thermal cleaning is longer, Si atoms can be further reduced.

As described above, the manufacturing method may further comprise, between the step P3 of performing the thermal cleaning and the step P5 of growing the second semiconductor 3, a step P4 of raising a temperature in the growth furnace C in an atmosphere containing phosphine in place of AsH₃. Then, a flow rate of arsine during the thermal cleaning may be larger than a flow rate of phosphine during the step P4 of raising the temperature. In this way, by setting the flow rate of AsH₃ larger than the subsequent flow rate of phosphine, the flow rate of AsH₃ becomes large, so Si atoms can be further reduced.

As described above, the first semiconductor 2 may comprise (InP)_{1-z}(In_{0.53}Ga_{0.47}As)_{z} (where 0≤z<1). In this case, it is possible to obtain the semiconductor device 1 comprising the first semiconductor 2 that is lattice-matched to InP.

### First Comparative Example

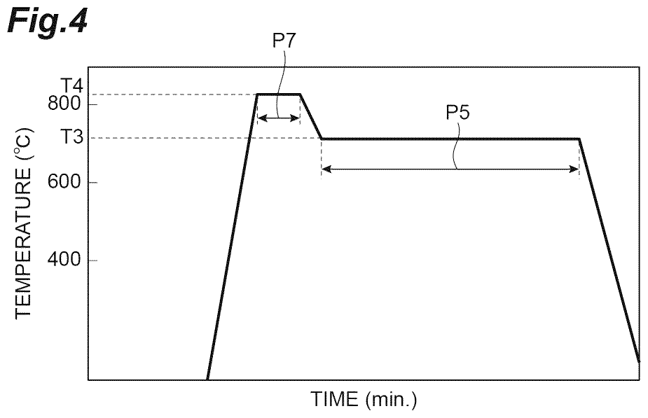

First, as the first comparative example, an InP substrate (corresponding to the first semiconductor 2 described above) was subjected to thermal cleaning with PH₃, and then an InP layer (corresponding to the second semiconductor 3 described above) was grown on the InP substrate. FIG. 4 is a diagram showing a temporal change in a set temperature in a growth furnace in this comparative example. In FIG. 4, the vertical axis represents temperature (° C.), and the horizontal axis represents time (minutes). As shown in FIG. 4, the manufacturing method according to this comparative example includes at least two steps P5 and P7. Step P5 is the same as step P5 of the above embodiment. In step P5, while maintaining the set temperature of the growth furnace at a set temperature T3, an indium source gas (trimethylindium) was supplied in addition to PH₃, thereby growing an InP layer on the InP substrate.

Step P7 was performed before step P5. In step P7, by supplying PH₃ into the growth furnace, the inside of the growth furnace was filled with an atmosphere containing only PH₃ and a carrier gas. A flow rate of PH₃ was set to 1500 sccm. Then, by maintaining the set temperature of the growth furnace at a set temperature T4, thermal cleaning was performed on the surface of the InP substrate. At this time, for three InP substrates, the set temperature T4 and processing time for the thermal cleaning were set to 800° C. and 15 minutes, 830° C. and 5 minutes, and 830° C. and 15 minutes, respectively. An InP substrate that was not subjected to thermal cleaning was also prepared.

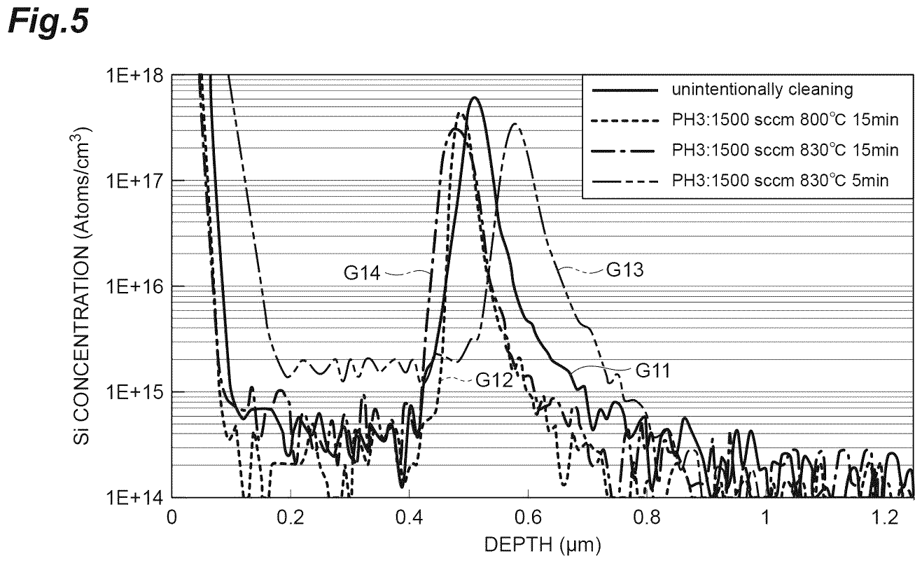

FIG. 5 is a graph showing a profile of Si concentration in a thickness direction as a result of performing secondary ion mass spectrometry on four samples prepared in the comparative example. In FIG. 5, the vertical axis represents Si concentration (Atoms/cm³), and the horizontal axis represents the position in the thickness direction, i.e., the depth (μm). In FIG. 5, a curve G11 shows the case where thermal cleaning was not performed. A curve G12 shows the case where the set temperature T4 and processing time for the thermal cleaning were set to 800° C. and 15 minutes. A curve G13 shows the case where the set temperature T4 and processing time for the thermal cleaning were set to 830° C. and 5 minutes. A curve G14 shows the case where the set temperature T4 and processing time for the thermal cleaning were set to 830° C. and 15 minutes.

Referring to FIG. 5, in all samples, a peak of Si concentration exists in the range of 0.4 μm to 0.7 μm in depth, that is, near the interface between the InP substrate and the InP layer. Compared to the sample not subjected to thermal cleaning (curve G11), the Si concentration is slightly reduced in the samples subjected to thermal cleaning (curves G12 to G14). Furthermore, the higher the set temperature T4 and the longer the processing time, the more the Si concentration is reduced. This indicates that even in thermal cleaning using PH₃, Si atoms present at the interface between the InP substrate and the InP layer are slightly reduced.

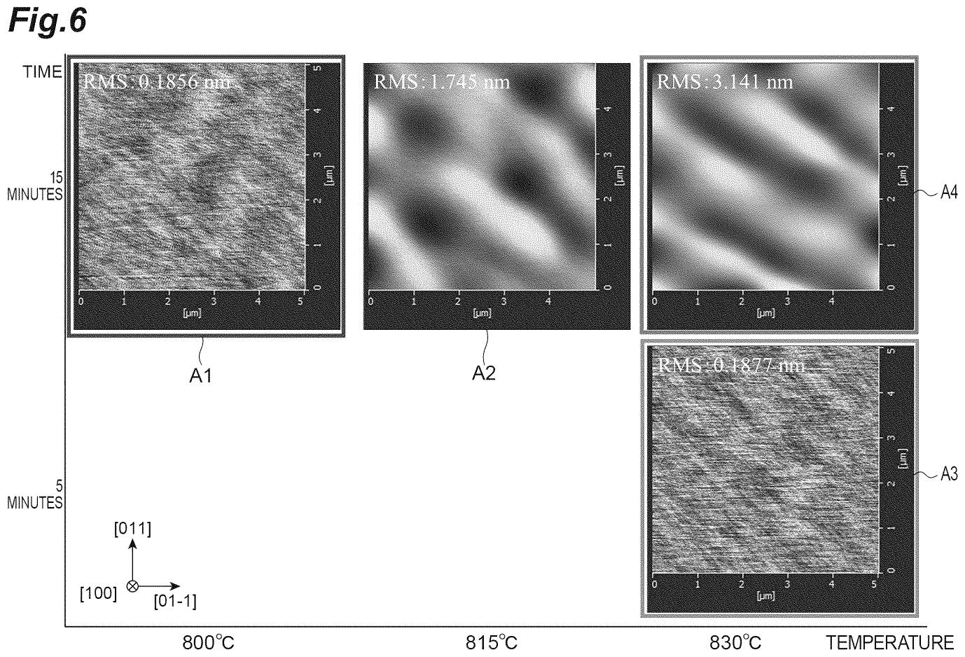

FIG. 6 shows a micrograph of the surface of the InP substrate after the thermal cleaning. In FIG. 6, photographs A1 to A4 show results where the set temperature T4 and processing time were set to 800° C. and 15 minutes, 815° C. and 15 minutes, 830° C. and 5 minutes, and 830° C. and 15 minutes, respectively. Referring to FIG. 6, it can be seen that the higher the set temperature T4 and the longer the processing time, the more the surface flatness deteriorates. When the surface roughness, which is an index of surface flatness, was measured, the surface roughness was 0.1856 nm at 800° C. for 15 minutes, 1.745 nm at 815° C. for 15 minutes, 0.1877 nm at 830° C. for 5 minutes, and 3.141 nm at 830° C. for 15 minutes. Thus, in high-temperature or long-time thermal cleaning, the surface flatness of the InP substrate deteriorates significantly.

According to the comparative example described above, when PH₃ is used for thermal cleaning, the effect of reducing Si atoms is small, and if the processing temperature is increased and the processing time is prolonged to reduce more Si atoms, the surface flatness of the InP substrate is impaired, and therefore it can be said that application to practical devices is difficult.

### Second Comparative Example

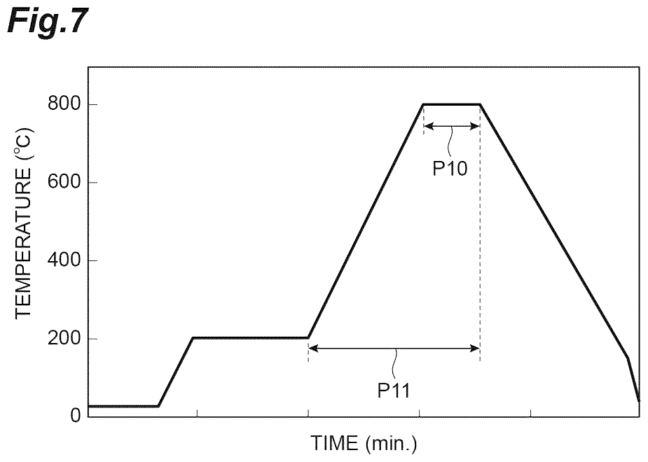

Next, as the second comparative example, an InP substrate was subjected to thermal cleaning in an AsH₃ atmosphere. FIG. 7 is a diagram showing a temporal change in a set temperature in a growth furnace in this comparative example. In FIG. 7, the vertical axis represents temperature (° C.), and the horizontal axis represents time (minutes). As shown in FIG. 7, in this comparative example, after placing an InP substrate in a growth furnace, the set temperature of the growth furnace was first kept at 200° C., then the set temperature of the growth furnace was raised to 800° C., and thermal cleaning of the InP substrate was performed at a furnace temperature of 800° C. In this comparative example, a plurality of InP substrates were divided into the first group and the second group. The first group is a group in which AsH₃ is supplied only during a period P10 (5 minutes) in which the furnace temperature is maintained at 800° C. The second group is a group in which AsH₃ is supplied during a period P11 (15 minutes) including a period when the furnace temperature rises from 200° C. to 800° C. and a period when the furnace temperature is maintained at 800° C. For some of the InP substrates in the first group, a supply rate of AsH₃ was set to 100 sccm. For the remaining InP substrates in the first group, a supply rate of AsH₃ was set to 400 sccm. For the InP substrates of the second group, a supply rate of AsH₃ was set to 100 sccm. 1 sccm is equal to 1.67×10⁻⁸ m³/s.

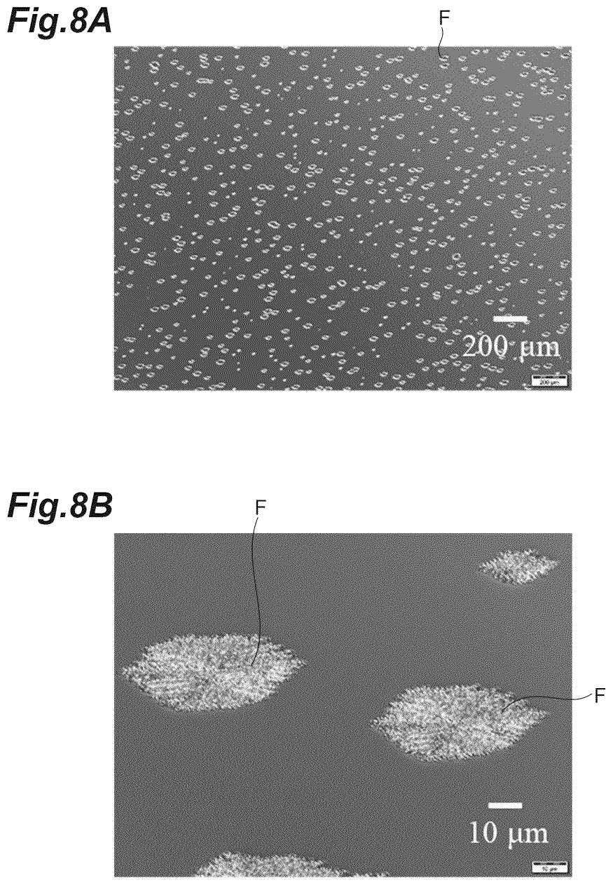

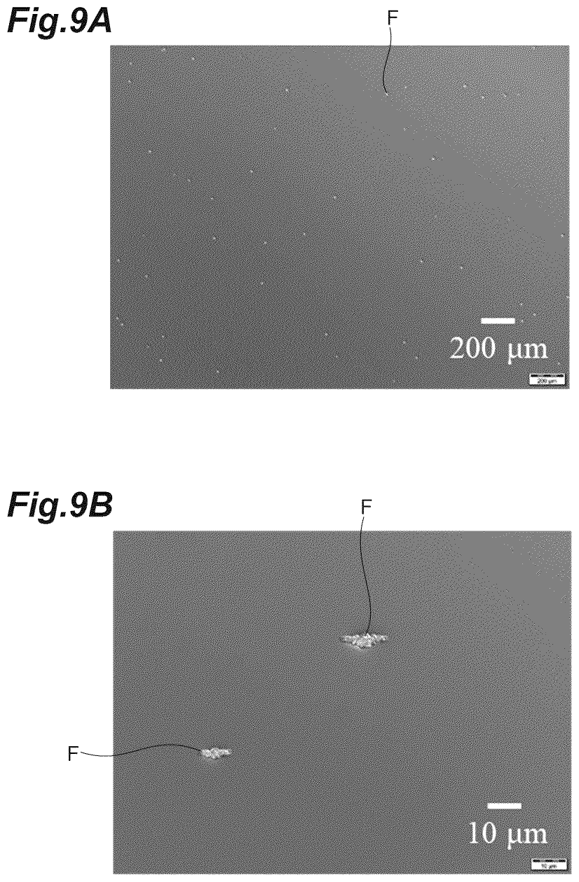

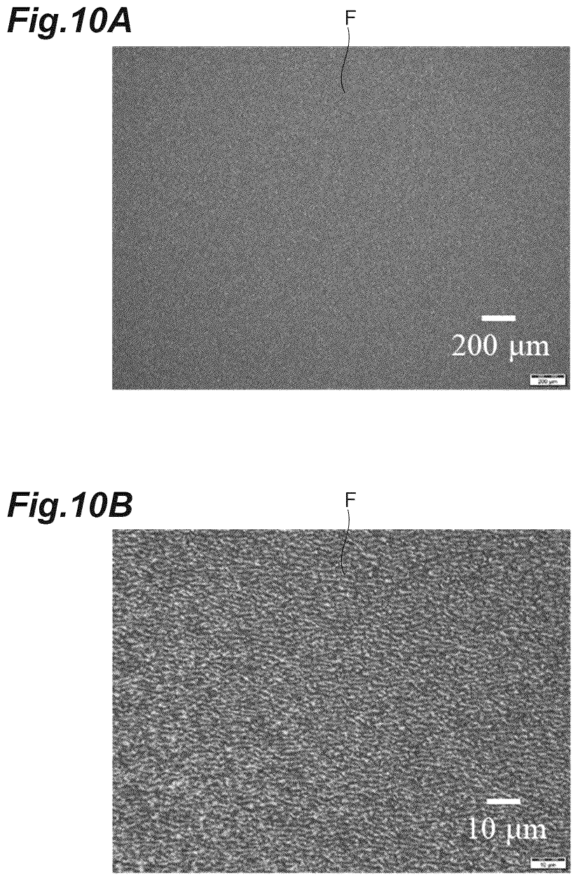

FIGS. 8A, 8B, 9A, 9B, 10A, and 10B are micrographs of the surface of the InP substrate. FIGS. 8A and 8B show the surface of the InP substrate for which the supply rate of AsH₃ was set to 400 sccm in the first group. FIGS. 9A and 9B show the surface of the InP substrate for which the supply rate of AsH₃ was set to 100 sccm in the first group. FIGS. 10A and 10B show the surface of the InP substrate in the second group. The photographs in FIGS. 8B, 9B, and 10B are enlarged views of the photographs in FIGS. 8A, 9A, and 10A, respectively. Referring to these figures, it can be seen that when AsH₃ is supplied to the surface of the InP substrate in a high-temperature state such as 800° C., phosphorus atoms are desorbed due to thermal degradation of InP, and the thereby precipitated indium atoms bond with arsenic atoms, resulting in the generation of numerous unintended deposits F on the surface.

According to the comparative example described above, even when AsH₃ is used for thermal cleaning, if the processing temperature is high, unintended deposits F are generated on the surface of the InP substrate, so it can be said that application to practical devices is difficult.

### Reference Example

Next, as a reference example, thermal cleaning was performed on an InP substrate without supplying either AsH₃ or PH₃ into the growth furnace (while supplying only a carrier gas). In this reference example, a plurality of InP substrates were divided into four groups, and only the set temperature during thermal cleaning (800° C. in FIG. 7) among the temporal changes in the set temperature shown in FIG. 7 was set to 590° C., 595° C., 600° C., and 620° C. for the four groups, respectively.

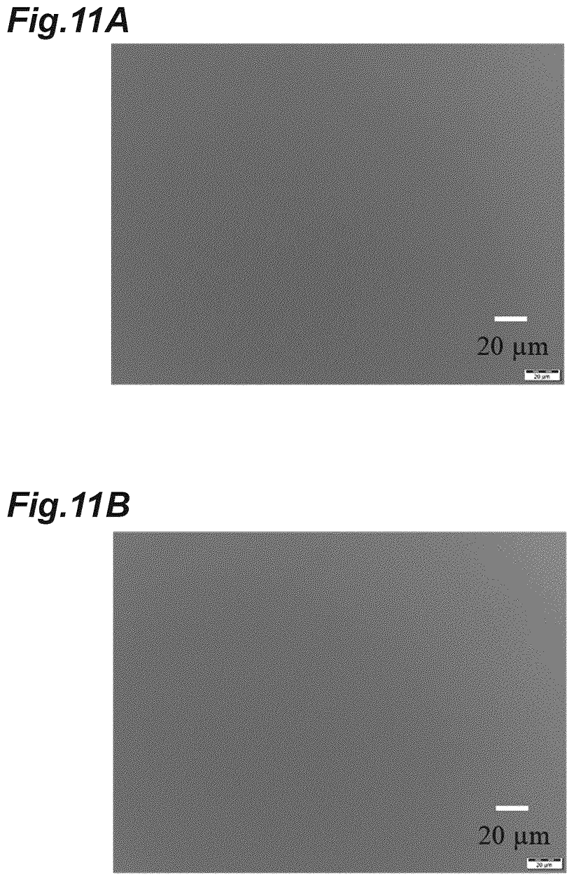

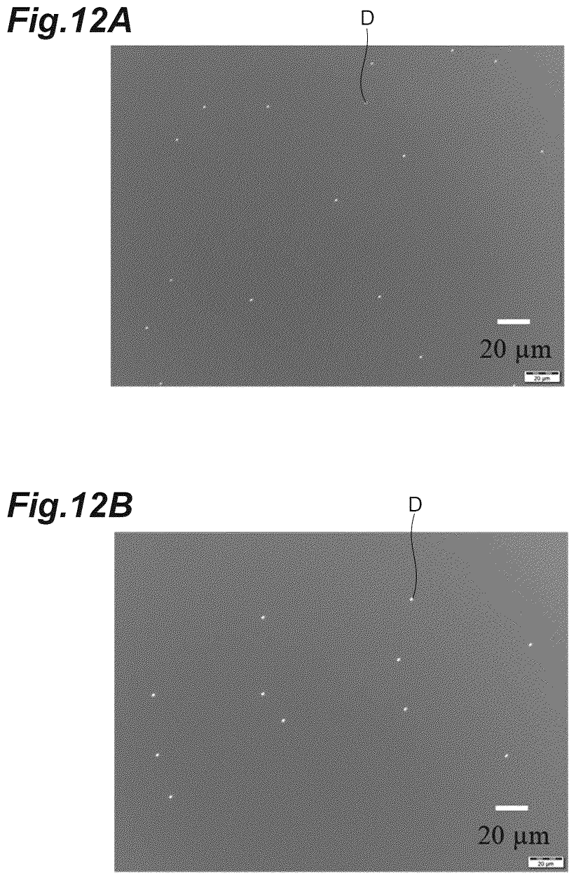

FIGS. 11A, 11B, 12A, and 12B are micrographs of the surface of the InP substrate after the thermal cleaning in this reference example. FIGS. 11A and 11B show results where the set temperature during thermal cleaning was set to 590° C. and 595° C., respectively. FIGS. 12A and 12B show results where the set temperature during thermal cleaning was set to 600° C. and 620° C., respectively. As shown in FIGS. 12A and 12B, when the set temperature during thermal cleaning was set to 600° C. or higher, the generation of unintended deposits D was observed on the surface of the InP substrate. As shown in FIGS. 11A and 11B, when the set temperature during thermal cleaning was set to 595° C. or less, the generation of unintended deposits D was not observed on the surface of the InP substrate.

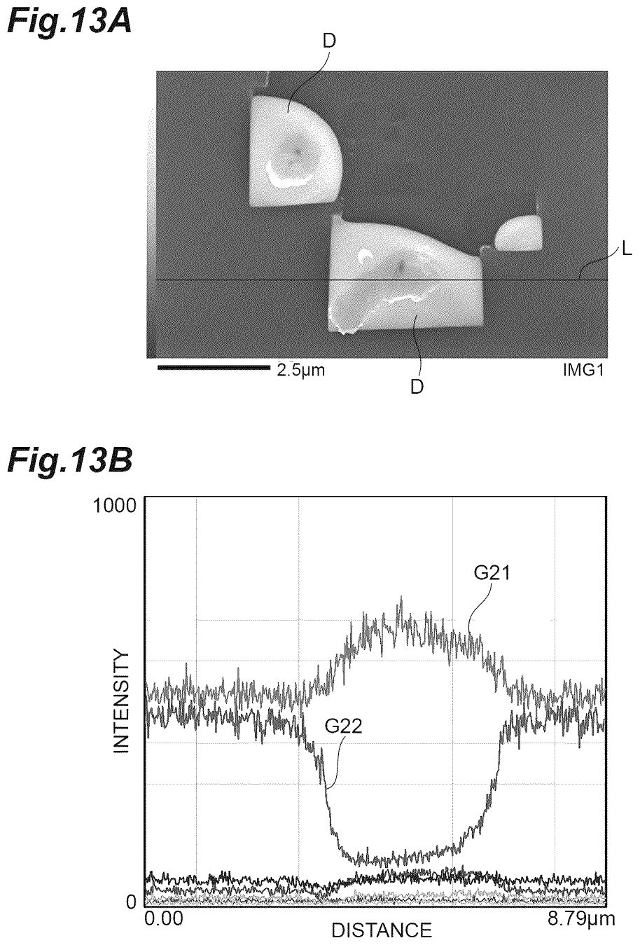

FIG. 13A is an enlarged view of the unintended deposits D in FIG. 12B. FIG. 13B is a graph showing a result of analyzing the unintended deposits D along a line L by energy dispersive X-ray spectroscopy (EDS). In FIG. 13B, a line G21 indicates the X-ray intensity due to In, i.e., the indium concentration, and a line G22 indicates the X-ray intensity due to phosphorus, i.e., the phosphorus concentration. From this analysis result, it was found that the unintended deposits D are precipitated indium due to the desorption of phosphorus at high temperature. Therefore, if the set temperature for thermal cleaning is 595° C. or less, which corresponds to a temperature of the InP substrate of 476° C. or less, no indium precipitates at all, which is more preferable.

### First Example

Next, as the first example, an InP substrate was subjected to thermal cleaning in an AsH₃ atmosphere, and then an InP layer was grown on the InP substrate. In the present example, the temporal change in the set temperature shown in FIG. 3 was applied, and the set temperature T2 during thermal cleaning was set to 585° C., and the set temperature T3 during the growth of the InP layer was set to 775° C. Then, a plurality of InP substrates were divided into three groups, and the processing time of the thermal cleaning (the length of the period during which AsH₃ was supplied while maintaining the set temperature T2) was set to 0 minutes, 30 minutes, and 60 minutes for the three groups, respectively. A supply rate of AsH₃ during the thermal cleaning was set to 1 slm.

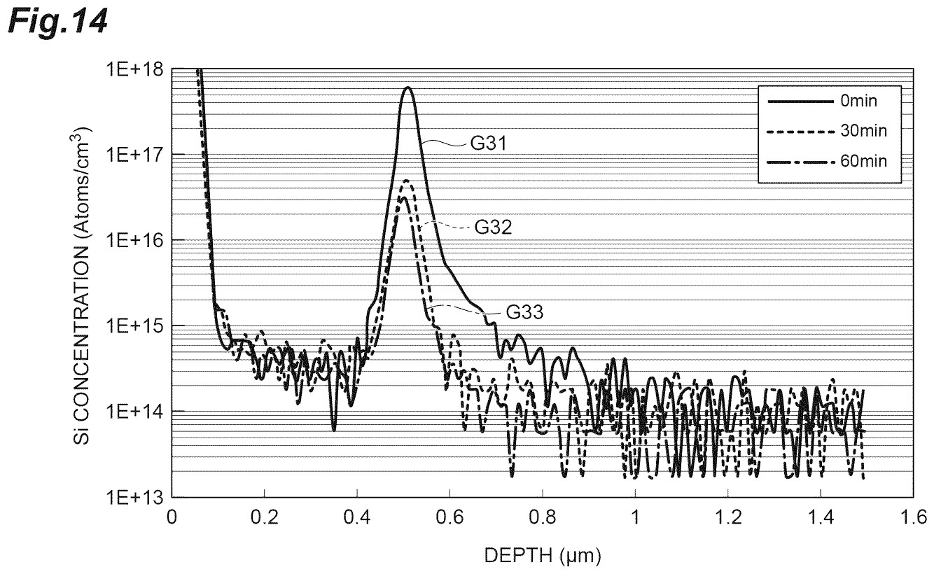

FIG. 14 is a graph showing a profile of Si concentration in a thickness direction as a result of performing secondary ion mass spectrometry on samples of the three groups prepared in the present example. In FIG. 14, the vertical axis represents Si concentration (Atoms/cm³), and the horizontal axis represents the position in the thickness direction, i.e., the depth (μm). In FIG. 14, a curve G31 shows the case where the processing time of the thermal cleaning was set to 0 minutes, i.e., thermal cleaning was not performed. A curve G32 shows the case where the processing time of the thermal cleaning was set to 30 minutes. A curve G33 shows the case where the processing time of the thermal cleaning was set to 60 minutes.

Referring to FIG. 14, in all samples, a peak of Si concentration exists in the range of 0.4 μm to 0.7 μm in depth, that is, near the interface between the InP substrate and the InP layer. Compared to the sample not subjected to thermal cleaning (curve G31), the Si concentration is significantly reduced in the samples subjected to thermal cleaning (curves G32, G33). Furthermore, the longer the processing time of the thermal cleaning, the more the Si concentration is reduced. Compared to the graph shown in FIG. 5, the Si concentration is reduced by about one order of magnitude. This indicates that thermal cleaning at a temperature lower than the growth temperature of the InP layer and in an AsH₃ atmosphere can significantly reduce Si atoms present at the interface between the InP substrate and the InP layer.

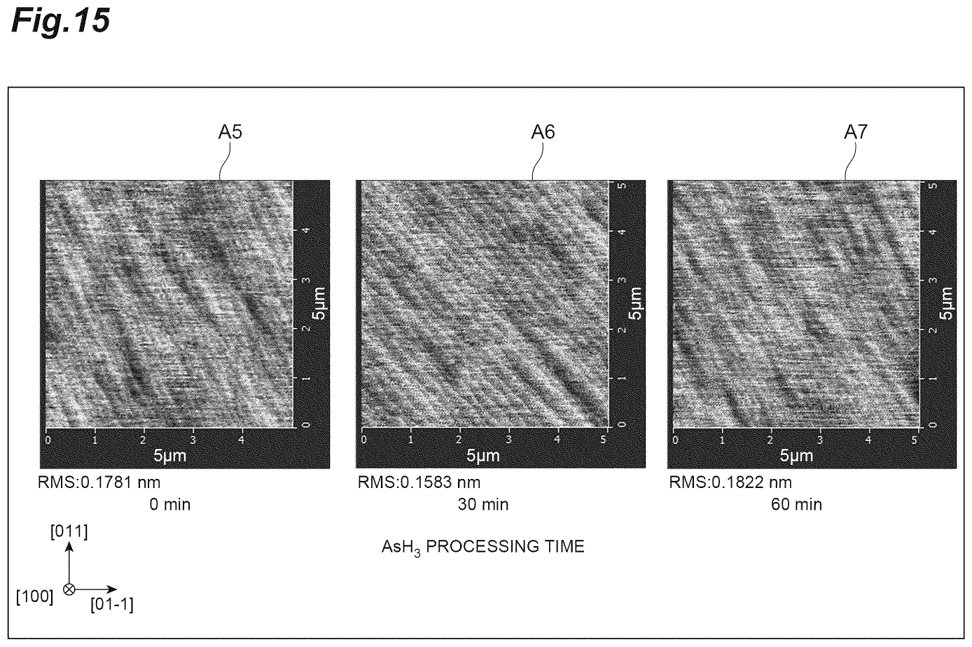

FIG. 15 shows a micrograph of the surface of the InP substrate after the thermal cleaning. In FIG. 15, photographs A5 to A7 show results where the processing time was set to 0 minutes, 30 minutes, and 60 minutes, respectively. Referring to FIG. 15, it can be seen that the surface flatness is maintained regardless of the processing time. When the surface roughness, which is an index of surface flatness, was measured, the surface roughness was 0.1781 nm for the sample with a processing time of 0 minutes, 0.1583 nm for the sample with a processing time of 30 minutes, and 0.1822 nm for the sample with a processing time of 60 minutes. Thus, in all samples, the surface roughness was 0.3 nm or less, which is a guideline for good flatness. In this way, by the thermal cleaning at a temperature lower than the growth temperature of the InP layer and in an AsH₃ atmosphere, good surface flatness of the InP substrate can be maintained even if the processing time is prolonged. Therefore, the effect of reducing Si atoms can be enhanced by lengthening the processing time. In this example, the unintended deposits F (see FIGS. 8A, 8B, 9A, 9B, 10A and 10B) observed in the high-temperature thermal cleaning were not observed at all even by Dynamic Force Mode (DFM) of a scanning probe microscope.

### Second Example

Next, as the second example, an InP substrate was subjected to thermal cleaning in an AsH₃ atmosphere, and then an InP layer was grown on the InP substrate. In the present example as well, the temporal change in the set temperature shown in FIG. 3 was applied, and the set temperature T2 during thermal cleaning was set to 585° C., and the set temperature T3 during the growth of the InP layer was set to 775° C. Then, a plurality of InP substrates were divided into five groups, and a supply rate and a supply time of AsH₃ during the thermal cleaning were set to 0 slm and 0 minutes, 0.5 slm and 30 minutes, 1.0 slm and 15 minutes, 1.0 slm and 30 minutes, and 1.0 slm and 60 minutes for the five groups, respectively. A volume of the growth furnace used was about 50265 cm³.

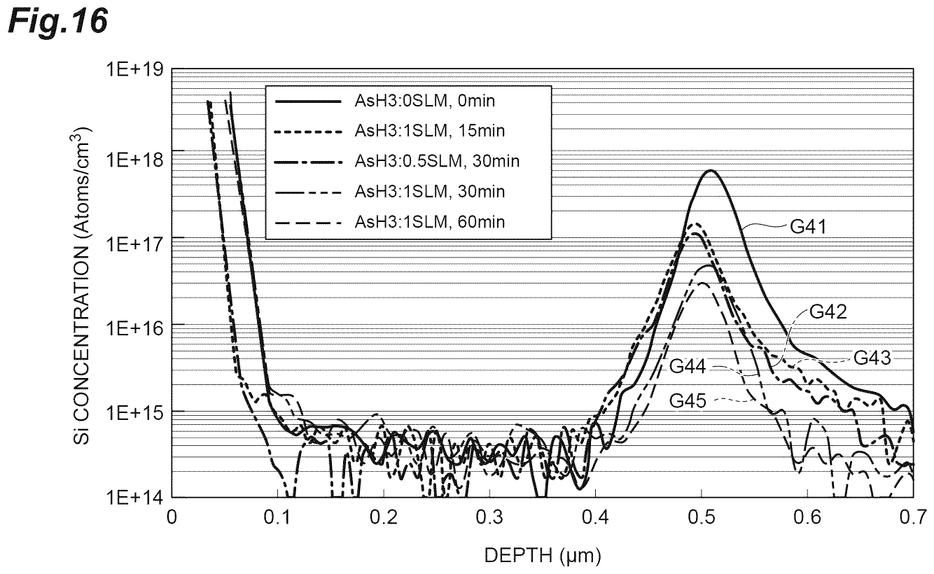

FIG. 16 is a graph showing a profile of Si concentration in a thickness direction as a result of performing secondary ion mass spectrometry on samples of the five groups prepared in the present example. In FIG. 16, the vertical axis represents Si concentration (Atoms/cm³), and the horizontal axis represents the position in the thickness direction, i.e., the depth (μm). In FIG. 16, a curve G41 shows the case where the processing time of the thermal cleaning was set to 0 minutes, i.e., thermal cleaning was not performed. A curve G42 shows the case where the supply rate and supply time of AsH₃ were set to 0.5 slm and 30 minutes. A curve G43 shows the case where the supply rate and supply time of AsH₃ were set to 1.0 slm and 15 minutes. A curve G44 shows the case where the supply rate and supply time of AsH₃ were set to 1.0 slm and 30 minutes. A curve G45 shows the case where the supply rate and supply time of AsH₃ were set to 1.0 slm and 60 minutes.

Referring to FIG. 16, compared to the sample not subjected to thermal cleaning (curve G41), the Si concentration is significantly reduced in the samples subjected to thermal cleaning (curves G42 to G45). Furthermore, the larger the total supply amount of AsH₃ (the product of the supply rate and the supply time), the more the Si concentration is reduced. This indicates that thermal cleaning at a temperature lower than the growth temperature of the InP layer and in an AsH₃ atmosphere can significantly reduce Si atoms present at the interface between the InP substrate and the InP layer.

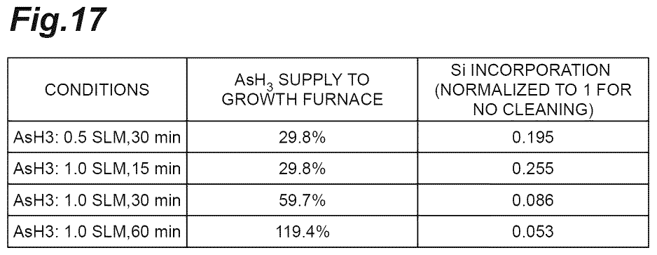

FIG. 17 is a chart showing a ratio (S/M) of a total supply amount S of AsH₃ to a volume M of the growth furnace and an incorporation amount of Si atoms (Si concentration) for four samples subjected to thermal cleaning. The ratio (S/M) is expressed as a percentage. The incorporation amount of Si atoms is calculated with the amount in the case where thermal cleaning is not performed as 1. Referring to FIG. 17, it can be seen that when the ratio (S/M) is 50% or more, in other words, when the total supply amount of AsH₃ is 50% or more with respect to the volume of the growth furnace, the incorporation amount of Si atoms is significantly (by one order of magnitude or more) reduced.

### Third Example

Next, as the third example, an InP substrate was subjected to thermal cleaning in an AsH₃ atmosphere, and then an InP layer was grown on the InP substrate. In the present example as well, the temporal change in the set temperature shown in FIG. 3 was applied. However, a plurality of InP substrates were divided into five groups, and the set temperature T2 during thermal cleaning was set to 450° C., 500° C., 540° C., and 585° C. for four of the groups, respectively. The remaining one group was not subjected to thermal cleaning. The set temperature T3 during the growth of the InP layer was set to 775° C. A supply rate and a supply time of AsH₃ were set to 1.0 slm and 30 minutes.

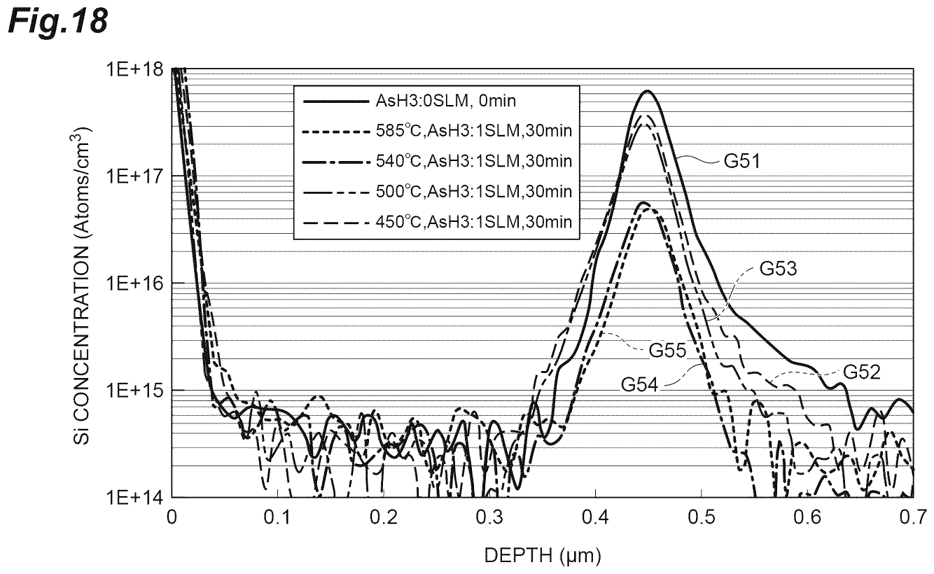

FIG. 18 is a graph showing a profile of Si concentration in a thickness direction as a result of performing secondary ion mass spectrometry on samples of the five groups prepared in the present example. In FIG. 18, the vertical axis represents Si concentration (Atoms/cm³), and the horizontal axis represents the position in the thickness direction, i.e., the depth (μm). In FIG. 18, a curve G51 shows the case where thermal cleaning was not performed. A curve G52 shows the case where the set temperature T2 was set to 450° C. A curve G53 shows the case where the set temperature T2 was set to 500° C. A curve G54 shows the case where the set temperature T2 was set to 540° C. A curve G55 shows the case where the set temperature T2 was set to 585° C.

Referring to FIG. 18, compared to the sample not subjected to thermal cleaning (curve G51), the Si concentration is reduced in the samples subjected to thermal cleaning (curves G52 to G55). In particular, when the set temperature T2 was set to 540° C. or more (corresponding to a temperature of the InP substrate of 417° C. or more), the Si concentration was significantly (by one order of magnitude or more) reduced. This indicates that thermal cleaning at a temperature lower than the growth temperature of the InP layer and in an AsH₃ atmosphere can significantly reduce Si atoms present at the interface between the InP substrate and the InP layer.

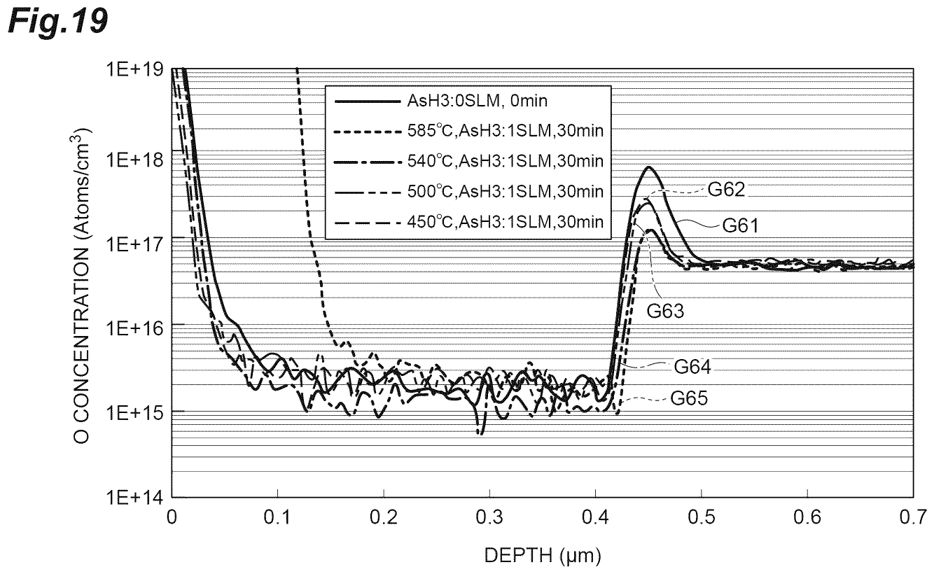

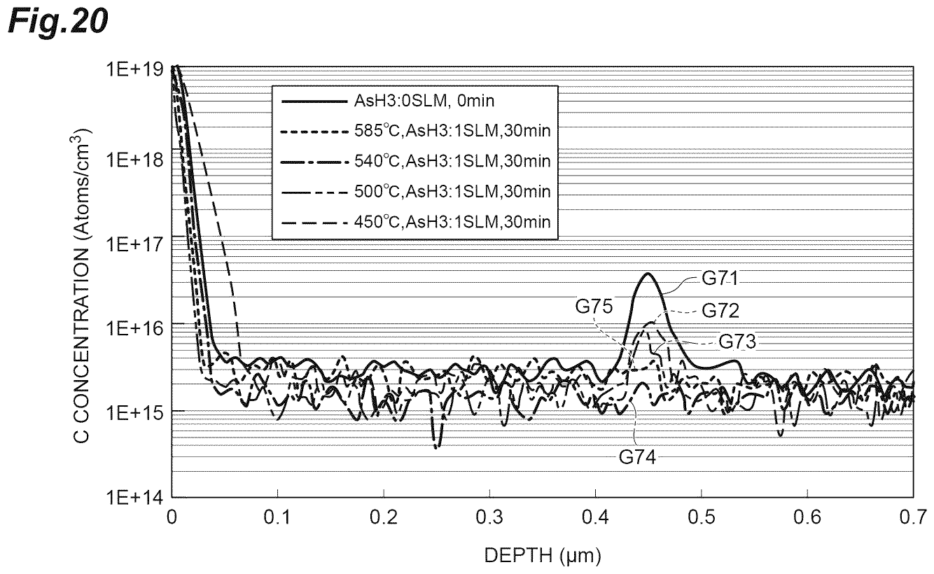

FIG. 19 is a graph showing a concentration profile of oxygen (O) atoms in the thickness direction in the present example. FIG. 20 is a graph showing a concentration profile of carbon (C) atoms in the thickness direction in the present example. In FIGS. 19 and 20, curves G61 and G71 show the case where thermal cleaning was not performed. Curves G62 and G72 show the case where the set temperature T2 was set to 450° C. Curves G63 and G73 show the case where the set temperature T2 was set to 500° C. Curves G64 and G74 show the case where the set temperature T2 was set to 540° C. Curves G65 and G75 show the case where the set temperature T2 was set to 585° C. As shown in FIGS. 19 and 20, by the thermal cleaning at a temperature lower than the growth temperature of the InP layer and in an AsH₃ atmosphere, not only Si atoms but also O atoms and C atoms are reduced at the interface between the InP substrate and the InP layer.

The method for manufacturing a semiconductor device according to the present disclosure is not limited to the embodiments described above, and various other modifications are possible. For example, the set temperature for the thermal cleaning and the temperature of the first semiconductor are not limited to the temperatures shown in the above embodiments and examples, and various temperatures can be adopted as long as they are lower than the set temperature and the temperature of the first semiconductor during the growth of the second semiconductor.

The method for manufacturing a semiconductor device according to the present disclosure is described as follows.

(1) A method for manufacturing a semiconductor device according to one aspect of the present disclosure manufactures a semiconductor device comprising a first semiconductor made of InP or InGaAsP and a second semiconductor provided on the first semiconductor. The method comprises a first step and a second step. In the first step, thermal cleaning is performed on a surface of the first semiconductor in a growth furnace in an atmosphere containing arsine. In the second step, the second semiconductor is grown on the surface of the first semiconductor in the growth furnace. A set temperature of the growth furnace during the thermal cleaning is set lower than a set temperature of the growth furnace during the growing the second semiconductor.

The present inventors have found that Si atoms present on the surface of a substrate or a semiconductor layer comprising InP or InGaAsP can be removed by performing thermal cleaning in an arsine (AsH₃) atmosphere. When performing thermal cleaning on the surface of a semiconductor made of InP or InGaAsP, if the substrate temperature is high, phosphorus atoms are desorbed due to thermal degradation of InP or InGaAsP, and indium atoms precipitate. When thermal cleaning is performed in an AsH₃ atmosphere, phosphorus atoms are desorbed and replaced by arsenic atoms, causing arsenic atoms to bond with indium atoms and generating unintended deposits on the surface. Therefore, the set temperature of the growth furnace during the thermal cleaning is set lower than the set temperature of the growth furnace during the growing the second semiconductor. This can prevent thermal degradation of InP or InGaAsP, reduce the desorption of phosphorus atoms, and reduce the generation of unintended deposits. From the above, according to the manufacturing method of (1), it is possible to reduce or remove Si atoms while reducing the generation of unintended deposits at the interface between the substrate or semiconductor layer comprising InP or InGaAsP, i.e., the first semiconductor, and another semiconductor layer grown thereon, i.e., the second semiconductor.

(2) In the manufacturing method according to (1), a temperature of the first semiconductor during the thermal cleaning may be lower than 534° C. In this case, thermal degradation of InP or InGaAsP can be reliably prevented.

(3) In the manufacturing method according to (1), a temperature of the first semiconductor during the thermal cleaning may be 476° C. or less. In this case, thermal degradation of InP or InGaAsP can be more reliably prevented.

(4) In the manufacturing method according to (1) or (2), a temperature of the first semiconductor during the thermal cleaning may be 417° C. or more. In this case, Si atoms can be further reduced.

(5) In the manufacturing method according to (1), the temperature of the first semiconductor during the thermal cleaning may be 417° C. or more and 476° C. or less. In this case, it is possible to achieve both further reduction of Si atoms and more reliable prevention of thermal degradation of InP or InGaAsP.

(6) In the manufacturing method according to any one of (1) to (5), a processing time of the thermal cleaning may be 30 minutes or more. In this case, Si atoms can be further reduced.

(7) In the thermal cleaning of the manufacturing method of any one of (1) to (6), a total supply amount of arsine may be 50% or more with respect to a volume of the growth furnace. In this case, Si atoms can be further reduced.

(8) In the manufacturing method according to any one of (1) to (7), a root mean square roughness of the surface of the first semiconductor after the thermal cleaning may be 0.3 nm or less. According to the manufacturing method according to any one of (1) to (6), it is thus possible to obtain a semiconductor device with less damage to the surface of the first semiconductor.

(9) In the manufacturing method according to any one of (1) to (8), a time for the thermal cleaning may be longer than a growth time of the second semiconductor. In this case, Si atoms can be further reduced.

(10) The manufacturing method according to any one of (1) to (9) may further comprise, between performing the thermal cleaning and the growing the second semiconductor, a step of raising a temperature in the growth furnace in an atmosphere containing phosphine in place of arsine. Then, a flow rate of arsine during the thermal cleaning may be larger than a flow rate of phosphine during the step of raising the temperature. In this way, by setting the flow rate of arsine larger than the subsequent flow rate of phosphine, Si atoms can be further reduced.

(11) In the manufacturing method according to any one of (1) to (10), the first semiconductor may comprise (InP)_{1-z}(In_{0.53}Ga_{0.47}As)_{z} (where 0≤z<1). In this case, it is possible to obtain a semiconductor device comprising the first semiconductor that is lattice-matched to InP.

What is claimed is:

1. A method for manufacturing a semiconductor device comprising a first semiconductor made of InP or InGaAsP and a second semiconductor provided on the first semiconductor, the method comprising:
performing thermal cleaning on a surface of the first semiconductor in a growth furnace in an atmosphere containing arsine; and
growing the second semiconductor on the surface of the first semiconductor in the growth furnace,
wherein a set temperature of the growth furnace during the thermal cleaning is lower than a set temperature of the growth furnace during the growing the second semiconductor.

2. The method for manufacturing a semiconductor device according to claim 1, wherein a temperature of the first semiconductor during the thermal cleaning is lower than 534° C.

3. The method for manufacturing a semiconductor device according to claim 1, wherein a temperature of the first semiconductor during the thermal cleaning is 476° C. or less.

4. The method for manufacturing a semiconductor device according to claim 1, wherein a temperature of the first semiconductor during the thermal cleaning is 417° C. or more.

5. The method for manufacturing a semiconductor device according to claim 1, wherein a temperature of the first semiconductor during the thermal cleaning is 417° C. or more and 476° C. or less.

6. The method for manufacturing a semiconductor device according to claim 1, wherein a processing time of the thermal cleaning is 30 minutes or more.

7. The method for manufacturing a semiconductor device according to claim 1, wherein in the thermal cleaning, a total supply amount of arsine is 50% or more with respect to a volume of the growth furnace.

8. The method for manufacturing a semiconductor device according to claim 1, wherein after the thermal cleaning, a root mean square roughness of the surface of the first semiconductor is 0.3 nm or less.

9. The method for manufacturing a semiconductor device according to claim 1, wherein a time for the thermal cleaning is longer than a growth time of the second semiconductor.

10. The method for manufacturing a semiconductor device according to claim 1, further comprising, between performing the thermal cleaning and the growing of the second semiconductor,
raising a temperature in the growth furnace in an atmosphere containing phosphine in place of arsine,
wherein a flow rate of arsine during the thermal cleaning is larger than a flow rate of phosphine during the raising the temperature.

11. The method for manufacturing a semiconductor device according to claim 1, wherein the first semiconductor comprises (InP)_{1-z}(In_{0.53}Ga_{0.47}As)_{z} (where 0≤z<1).
